(19) United States
(12) Patent Application Publication
(10) Pub. No.: US 2026/0006962 A1
(43) Pub. Date: Jan. 1, 2026

(54) DISPLAY DEVICE, METHOD FOR MANUFACTURING THE SAME, AND ELECTRONIC DEVICE

(71) Applicant: Samsung Display Co., LTD., Yongin-si (KR)

(72) Inventors: DONGYEON CHO, Yongin-si (KR); JUNGWOON JUNG, Yongin-si (KR)

(21) Appl. No.: 19/061,284

(22) Filed: Feb. 24, 2025

(30) Foreign Application Priority Data
Jun. 27, 2024 (KR) 10-2024-0084510

(51) Int. Cl. H10H 29/37; H10H 29/01; H10H 29/851

(52) U.S. Cl. CPC H10H 29/37; H10H 29/012; H10H 29/851

(57) ABSTRACT

A display device includes: a substrate including a light emitting area and a non-light emitting area adjacent to the light emitting area; a circuit layer on the substrate; a light emitting element in the light emitting area on the circuit layer and including a first electrode, a light emitting layer including quantum dots and on the first electrode, and a second electrode on the light emitting layer; a pixel defining layer in the non-light emitting area on the circuit layer, and defining a pixel opening exposing at least a portion of an upper surface of the first electrode and where the light emitting layer is located; and a hydrogen injection layer surrounding a side surface of the pixel defining layer and including silicone compound.

### CROSS-REFERENCE TO RELATED APPLICATION

The present application claims priority to and benefits of Korean Patent Application No. 10-2024-0084510, filed on Jun. 27, 2024, in the Korean Intellectual Property Office, the entire disclosure of which is incorporated herein by reference.

### BACKGROUND

### 1. Field

Aspects of some embodiments relate to a display device, a method for manufacturing the same, and an electronic device.

### 2. Description of the Related Art

As information technology develops, the importance of display devices, which provide a communication medium between users and information, is being highlighted. Accordingly, the use of display devices such as liquid crystal display devices, organic light emitting display devices, plasma display devices, and the like is increasing.

For example, an organic light emitting display device uses a self-luminous light-emitting element which realizes display by emitting light from a light emitting material including an organic compound. Recently, in order to relatively improve the color reproducibility of a display device, the development of a light-emitting element made of a light-emitting material using quantum dots is in progress, and there is a demand for relatively improving the luminous efficiency of the light-emitting element including quantum dots.

The above information disclosed in this Background section is only for enhancement of understanding of the background and therefore the information discussed in this Background section does not necessarily constitute prior art.

### SUMMARY

Aspects of some embodiments relate to a display device, a method for manufacturing the same, and an electronic device. For example, aspects of some embodiments relate to the display device which provides visual information and the method for manufacturing the same.

Aspects of some embodiments include a display device with relatively improved luminous efficiency.

Aspects of some embodiments include a method for manufacturing the display device.

Aspects of some embodiments include an electronic device including display device.

According to some embodiments of the present disclosure, a display device includes a substrate including a light emitting area and a non-light emitting area adjacent to the light emitting area, a circuit layer on the substrate, a light emitting element in the light emitting area on the circuit layer and including a first electrode, a light emitting layer including quantum dots and on the first electrode, and a second electrode on the light emitting layer, a pixel defining layer in the non-light emitting area on the circuit layer, and defining a pixel opening exposing at least a portion of an upper surface of the first electrode and where the light emitting layer is located, and a hydrogen injection layer surrounding a side surface of the pixel defining layer and including silicone compound.

According to some embodiments, the hydrogen injection layer may include silicon nitride (SiNₓ).

According to some embodiments, the hydrogen injection layer may expose an upper surface of the pixel defining layer.

According to some embodiments, an upper surface of the hydrogen injection layer may have liquid repellent.

According to some embodiments, an upper surface of the hydrogen injection layer may include a fluorine group.

According to some embodiments, a thickness of the hydrogen injection layer may be in a range from 5 nm to from 30 nm.

According to some embodiments, a hydrogen concentration contained in the hydrogen injection layer may be in a range of 1.0×10²² atoms/cm³ to 1.0×10²³ atoms/cm³.

According to some embodiments, the hydrogen injection layer may expose at least portion of the upper surface of the first electrode in the pixel opening.

According to some embodiments, the circuit layer may include at least one transistor including an oxide semiconductor.

According to some embodiments, the pixel defining layer may include an organic material or an inorganic material.

According to some embodiments, the first electrode may be an anode electrode, the second electrode may be a cathode electrode, and the light emitting element may further include a hole transport layer between the first electrode and the light emitting layer, a hole injection layer between the first electrode and the hole transport layer, and an electron transport layer between the light emitting layer and the second electrode.

According to some embodiments, the first electrode may be a cathode electrode, the second electrode may be an anode electrode, and the light emitting element may further include an electron transport layer between the first electrode and the light emitting layer, a hole transport layer between the light emitting layer and the second electrode, and a hole injection layer between the light emitting layer and the hole transport layer.

According to some embodiments of the present disclosure, in a method for manufacturing the display device, the method includes forming a circuit layer on a substrate including a light emitting area and a non-light emitting area adjacent to the light-emitting area, forming a first electrode in the light emitting area on the circuit layer, forming a pixel defining layer in the non-light emitting area on the circuit layer, and defining a pixel opening exposing at least a portion of an upper surface of the first electrode, forming a hydrogen injection layer surrounding a side surface of the pixel defining layer and including silicone compound, forming a light emitting layer including quantum dots on the first electrode, and forming a second electrode on the light emitting layer.

According to some embodiments, forming the hydrogen injection layer may include forming a preliminary hydrogen injection layer on the first electrode and on the pixel defining layer and forming the hydrogen injection layer by removing a portion of the preliminary hydrogen injection layer through an etching process.

According to some embodiments, the etching process may use a fluorine-based etching gas.

According to some embodiments, the fluorine-based etching gas may include at least one selected from a group consisting of CF₄, NF₃, and SF₆.

According to some embodiments, the preliminary hydrogen injection layer may be formed by chemical vapor deposition, and a deposition temperature for forming preliminary hydrogen injection layer may be in a range from 25° C. or more to 100° C. or less.

According to some embodiments, the hydrogen injection layer may be formed using silicon nitride.

According to some embodiments, the hydrogen injection layer may expose an upper surface of the pixel defining layer.

According to some embodiments, after forming the hydrogen injection layer, an upper surface of the pixel defining layer may have liquid repellent.

According to some embodiments of the present disclosure, an electronic device includes a display device and a processor for controlling the display device. According to some embodiments, the display device includes a substrate including a light emitting area and a non-light emitting area adjacent to the light emitting area, a circuit layer on the substrate, a light emitting element in the light emitting area on the circuit layer and including a first electrode, a light emitting layer including quantum dots and on the first electrode, and a second electrode on the light-emitting layer, a pixel defining layer in the non-light emitting area on the circuit layer, and defining a pixel opening exposing at least a portion of an upper surface of the first electrode and where the light emitting layer is located, and a hydrogen injection layer surrounding a side surface of the pixel defining layer and including silicone compound.

According to some embodiments, the display device may include a light emitting element including a first electrode, a light-emitting layer including quantum dots, and a second electrode sequentially arranged, a pixel defining layer defining a pixel opening exposing at least a portion of an upper surface of the first electrode and where the light emitting layer is arranged, and a hydrogen injection layer surrounding a side surface of the pixel defining layer and including silicone compound.

At this time, hydrogen contained in the hydrogen injection layer may flow into the light emitting element (for example, an electron transport layer). Accordingly, the luminous efficiency and luminance of the light emitting element may be relatively improved. In addition, by protecting the side surface of the pixel defining layer with the hydrogen injection layer, the yield of the light emitting element may be relatively improved.

### BRIEF DESCRIPTION OF THE DRAWINGS

Illustrative, non-limiting embodiments will be more clearly understood from the following detailed description in conjunction with the accompanying drawings.

FIG. 1 is a perspective view showing a display device according to some embodiments of the present disclosure.

FIG. 2 is an enlarged plan view of a portion of a display area of FIG. 1.

FIG. 3 is a cross-sectional view taken along the line I-I′ of FIG. 2.

FIG. 4 is an enlarged cross-sectional view of area A of FIG. 3.

FIG. 5 is a cross-sectional view showing an example of a light-emitting element.

FIG. 6 is a cross-sectional view showing another example of a light-emitting element.

FIGS. 7, 8, 9, 10, 11, 12, and 13 are cross-sectional views for explaining a method for manufacturing the display device of FIG. 3.

FIG. 14 is a block diagram showing an electronic device including the display device of FIG. 1.

FIG. 15 is a view illustrating an example in which the electronic device of FIG. 9 is implemented as a television.

FIG. 16 is a view illustrating an example in which the electronic device of FIG. 9 is implemented as a smartphone.

### DETAILED DESCRIPTION

Hereinafter, a display device according to some embodiments of the present disclosure will be explained in more detail with reference to the accompanying drawings. The same reference numerals are used for the same components in the drawings, and redundant descriptions of the same components will be omitted.

In this specification, a plane may be defined as a first direction DR1 and a second direction DR2 crossing the first direction DR1. For example, the first direction DR1 may be perpendicular to the second direction DR2. In addition, a third direction DR3 may be perpendicular to the plane. In the present specification a view from the third direction DR3 toward a display surface of a display device may be referred to as a “plan view.”

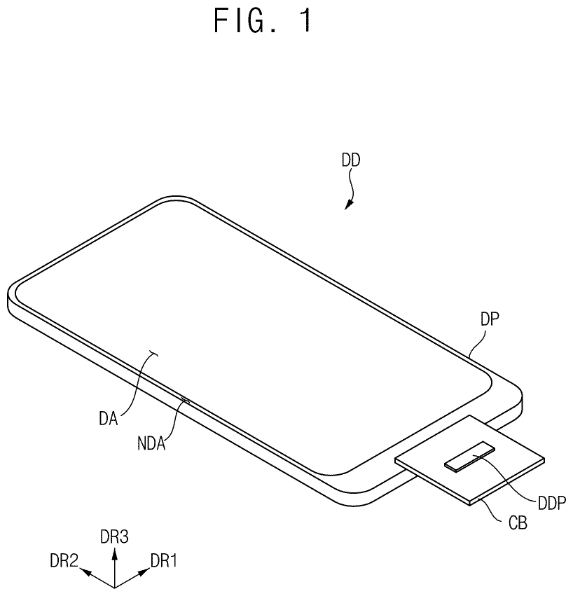

FIG. 1 is a perspective view showing a display device according to some embodiments of the present disclosure.

Referring to FIG. 1, a display device DD according to some embodiments of the present disclosure may include a display panel DP, a display driver DDP, and a circuit board CB.

The display panel DP may have a rectangular planar shape with a short side extending in the first direction DR1 and a long side extending in the second direction DR2. In this case, a corner where the short side and the long side of the display panel DP meet may be rounded to have a curvature (e.g., a set or predetermined curvature) or may be formed at a right angle. However, embodiments according to the present disclosure are not necessarily limited to this, and the display panel DP may have a polygonal, circular, irregular, or oval planar shape.

The display panel DP may be formed to be flat. However, embodiments according to the present disclosure are not limited to this, and the display panel DP may may include curved portions formed at the left and right ends and with a constant curvature or a changing curvature. In addition, the display panel DP may be flexible so that the display panel DP can be bent, folded, or rolled without damaging the display panel DP.

The display panel DP may include a display area DA and a non-display area NDA located around (e.g., in a periphery or outside a footprint of) the display area DA. For example, when the display panel DP includes a curved portion, the display area DA may overlap the curved portion. In this case, an image on the display panel DP may be displayed even on the curved portion.

A plurality of sub-pixels may be located in the display area DA. Each of the sub-pixels may include a driving transistor, at least one switching transistor, at least one light emitting element, and at least one capacitor. The driving transistor supplies a driving current to the light emitting element according to a data voltage applied to a gate electrode, thereby allowing the light emitting element to emit light. The capacitor may serve to keep the data voltage applied to the gate electrode of the driving transistor constant.

The non-display area NDA may be defined as an area from the edge of the display area DA to the edge of the display panel DP. A scan driver which provides scan signals to the sub-pixels and pad electrodes may be located in the non-display area NDA. For example, the pad electrodes may be located at a lower edge of the display panel DP, and the scan driver may be located at the left and/or right edges of the display panel DP.

The display driver DDP may receive digital video data and timing signals from the outside. The display driver DDP may convert digital video data into analog positive/negative data voltages and provide the converted data voltages to data lines located in the display area DA. The display driver DDP may generate and supply a scan control signal to control the operation timing of the scan driver. In addition, the display driver DDP may supply a driving voltage to the sub-pixels.

For example, the display driver DDP may be formed as an integrated circuit (IC) and attached to the circuit board CB using a chip on film (COF) method. Alternatively, the display driver DDP may be directly attached to the display panel DP using a chip on glass (COG) method, a chip on plastic (COP) method, or an ultrasonic bonding method.

The circuit board CB may be attached to the pad electrodes. For example, the circuit board CB may be attached to the pad electrodes through an anisotropic conductive film. Accordingly, the circuit board CB may be electrically connected to the pad electrodes. For example, the circuit board CB may be a flexible printed circuit board (FPCB), a printed circuit board (PCB), or a flexible film such as a chip on film.

The display device DD may be any one of an organic light emitting display device, a liquid crystal display device, a plasma display device, a field light emitting display device, an electrophoresis display device, an electrowetting display device, a quantum dot light emitting display device, and a micro LED display device. According to some embodiments, the display device DD may be a quantum dot light emitting display device.

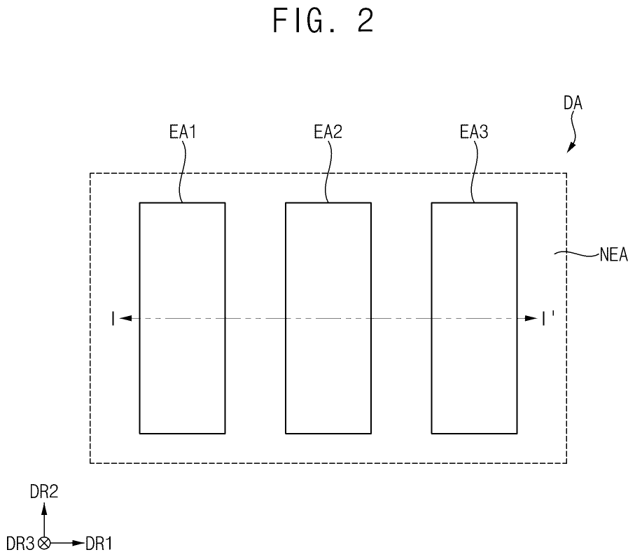

FIG. 2 is an enlarged plan view of a portion of a display area of FIG. 1.

Referring to FIG. 2, the display area DA may include a first light emitting area EA1, a second light emitting area EA2, a third light emitting area EA3, and a non-light emitting area NEA.

One sub-pixel may be located in each of the first light emitting area EA1, the second light emitting area EA2, and the third light emitting area EA3. Accordingly, the first light emitting area EA1, the second light-emitting area EA2, and the third light-emitting area EA3 may each be areas that emit light. The first emitting area EA1 may emit light of a first color, the second emitting area EA2 may emit light of a second color, and the third emitting area EA3 emits light of a third color. According to some embodiments, the first color may be red, the second color may be green, and the third color may be blue. However, embodiments according to the present disclosure are not necessarily limited thereto.

For example, the first light emitting area EA1, the second light emitting area EA2, and the third light emitting area EA3 may be repeatedly arranged along the first direction DR1. However, embodiments according to the present disclosure are not necessarily limited to this, and the arrangement of the first light emitting area EA1, the second light emitting area EA2, and the third light emitting area EA3 may be changed in various ways.

An area of the first light emitting area EA1, an area of the second light emitting area EA2, and an area of the third light emitting area EA3 may be the same (or substantially the same). Alternatively, the area of the first light emitting area EA1, the area of the second light emitting area EA2, and the area of the third light emitting area EA3 may be different from each other. However, embodiments according to the present disclosure are not necessarily limited thereto.

The non-light emitting area NEA may surround the first light emitting area EA1, the second light emitting area EA2, and the third light emitting area EA3. The non-light emitting area NEA may be an area that does not emit light.

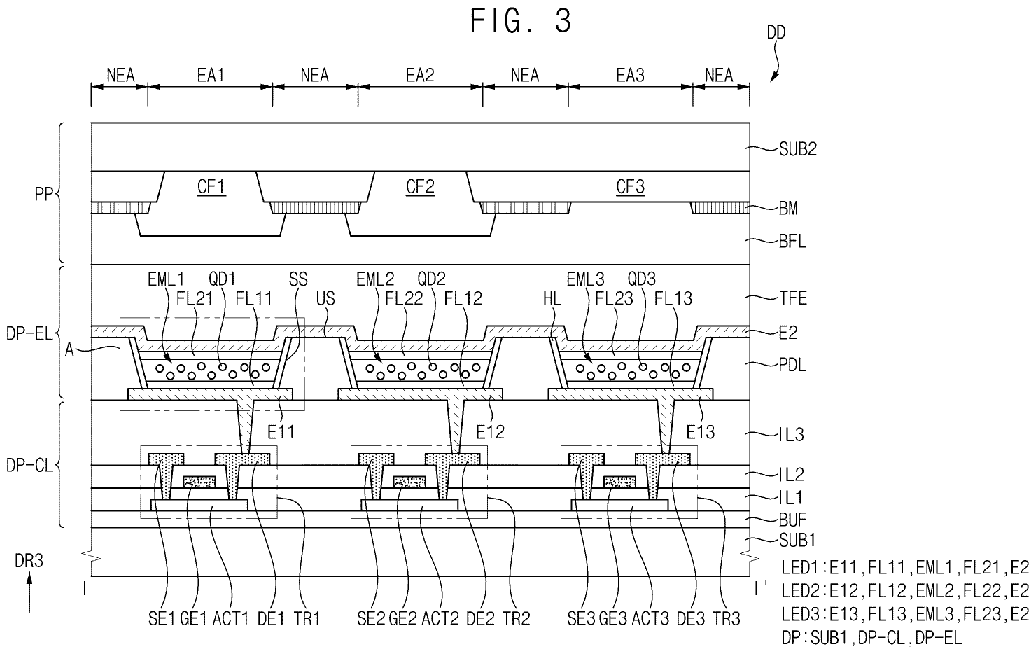

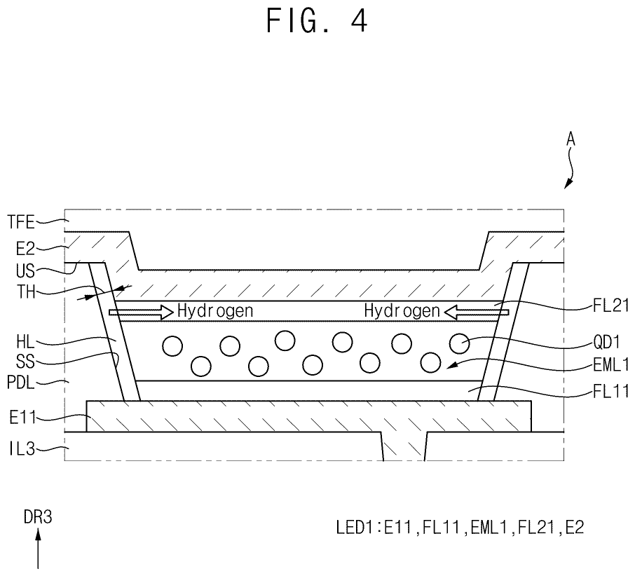

FIG. 3 is a cross-sectional view taken along line I-I′ of FIG. 2. FIG. 4 is an enlarged cross-sectional view of area A of FIG. 3.

Referring to FIGS. 3 and 4, the display device DD may include the display panel DP and an optical member PP. The display panel DP may include a first substrate SUB1, a circuit layer DP-CL, and a light emitting element layer DP-EL. The circuit layer DP-CL may include a buffer layer BUF, first, second, and third transistors TR1, TR2, and TR3, first, second, and third insulating layers IL1, IL2, and IL3. The light emitting element layer DP-EL may include a pixel defining layer PDL, a hydrogen injection layer HL, first, second, and third light emitting elements LED1, LED2, and LED3, and an encapsulation layer TFE. In addition, the optical member PP may include a second substrate SUB2, first, second, and third color filters CF1, CF2, and CF3, a light blocking layer BM, and a protective layer BFL.

Here, the first transistor TR1 may include a first active pattern ACT1, a first gate electrode GE1, a first source electrode SE1, and a first drain electrode DE1, the second transistor TR2 may include a second active pattern ACT2, a second gate electrode GE2, a second source electrode SE2, and a second drain electrode DE2, and the third transistor TR3 may include a third active pattern ACT3, a third gate electrode GE3, a third source electrode SE3, and a third drain electrode DE3.

In addition, the first light emitting element LED1 may include a first-first electrode E11, a first-first functional layer FL11, a first light emitting layer EML1, a second-first functional layer FL21, and a second electrode E2, which are sequentially stacked, the second light emitting element LED2 may include a first-second electrode E12, a first-second functional layer FL12, a second light-emitting layer EML2, a second-second functional layer FL22, and the second electrode E2, which are sequentially stacked, and the third light emitting element LED3 may include a first-third electrode E13, a first-third functional layer FL13, a third light-emitting layers EML3, a second-third functional layer FL23, and the second electrode E2.

The first substrate SUB1 may include a glass substrate, a metal substrate, or a plastic substrate. However, embodiments according to the present disclosure are not necessarily limited thereto. For example, the first substrate SUB1 may include an inorganic layer, an organic layer, or a composite material layer. In addition, the first substrate SUB1 may include a flexible substrate with flexibility.

The buffer layer BUF may be located on the first substrate SUB1. The buffer layer BUF may prevent or reduce instances of metal atoms, impurities, or contaminants diffusing from the first substrate SUB1 to the first, second, and third transistors TR1, TR2, and TR3. In addition, the buffer layer BUF may relatively improve the flatness of the surface of the first substrate SUB1 when the surface of the first substrate SUB1 is not uniform. For example, the buffer layer BUF may include an inorganic material such as silicon oxide, silicon nitride, silicon oxynitride, and the like. These can be used alone or in combination with each other.

The first, second, and third active patterns ACT1, ACT2, and ACT3 may be located on the buffer layer BUF. Each of the first, second, and third active patterns ACT1, ACT2, and ACT3 may include a metal oxide semiconductor, an inorganic semiconductor (e.g., amorphous silicon, poly silicon, and the like), or an organic semiconductor. According to some embodiments, each of the first, second, and third active patterns ACT1, ACT2, and ACT3 may include a metal oxide semiconductor. In addition, the first, second, and third active patterns ACT1, ACT2, and ACT3 are formed through the same process and may include the same material.

The metal oxide semiconductor may include. a binary compound (ABₓ), a ternary compound (ABₓC_{y}), a quaternary compound (ABₓC_{y}Dz), and the like containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include zinc oxide (e.g., ZnO or ZnO₂), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and the like. These can be used alone or in combination with each other.

Each of the first, second, and third active patterns ACT1, ACT2, and ACT3 may include a source area, a drain area, and a channel area located between the source area and the drain area. The source area and the drain area may be doped with impurities (e.g., n-type impurities or p-type impurities), and the channel area may be an area that is not doped with impurities.

The first insulating layer IL1 may be located on the buffer layer BUF. The first insulating layer IL1 may sufficiently cover the first, second, and third active patterns ACT1, ACT2, and ACT3, and have a flat (or substantially flat) upper surface without creating steps around the first, second, and third active patterns ACT1, ACT2, and ACT3. Alternatively, the first insulating layer IL1 may cover the first, second, and third active patterns ACT1, ACT2, and ACT3, and be arranged along the profile of each of the first, second, and third active patterns ACT1, ACT2, and ACT3 with a uniform thickness. For example, the first insulating layer IL1 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These can be used alone or in combination with each other.

The first, second, and third gate electrodes GE1, GE2, and GE3 may be located on the first insulating layer IL1. The first gate electrode GE1 may overlap the channel area of the first active pattern ACT1, the second gate electrode GE2 may overlap the channel area of the second active pattern ACT2, and the third gate electrode GE3 may overlap the channel area of the third active pattern ACT3.

Each of the first, second, and third gate electrodes GE1, GE2, and GE3 may include metal, alloy metal nitride, conductive metal oxide, transparent conductive material, and the like. Examples of the metal may include silver (Ag), molybdenum (Mo), aluminum (Al), tungsten (W), copper (Cu), nickel (Ni), chromium (Cr), titanium (Ti), and tantalum (Ta), platinum (Pt), scandium (Sc), and the like. Examples of the conductive metal oxide may include indium tin oxide, indium zinc oxide, and the like. In addition, examples of the metal nitride include aluminum nitride (AlNₓ), tungsten nitride (WNₓ), chromium nitride (CrNₓ), and the like. These can be used alone or in combination with each other.

The first, second, and third gate electrodes GE1, GE2, and GE3 may be formed through the same process and may include the same material.

The second insulating layer IL2 may be located on the first insulating layer IL1. The second insulating layer IL2 may sufficiently cover the first, second, and third gate electrodes GE1, GE2, and GE3, and have a flat (or substantially flat) upper surface without creating steps the first, second, and third gate electrodes GE1, GE2, and GE3. Alternatively, the second insulating layer IL2 may cover the first, second, and third gate electrodes GE1, GE2, and GE3, and be arranged along the profile of each of the first, second, and third gate electrodes GE1, GE2, and GE3 with a uniform thickness. For example, the second insulating layer IL2 may include an inorganic material such as silicon oxide, silicon nitride, silicon carbide, silicon oxynitride, silicon oxycarbide, and the like. These can be used alone or in combination with each other.

The first, second, and third source electrodes SE1, SE2, and SE3 may be located on the second insulating layer IL2. The first source electrode SE1 may be connected to the source region of the first active pattern ACT1 through a contact hole penetrating the first and second insulating layers IL1 and IL2. The second source electrode SE2 may be connected to the source region of the second active pattern ACT2 through a contact hole penetrating the first and second insulating layers IL1 and IL2. The third source electrode SE3 may be connected to the source region of the third active pattern ACT3 through a contact hole penetrating the first and second insulating layers IL1 and IL2.

The first, second, and third drain electrodes DE1, DE2, and DE3 may be located on the second insulating layer IL2. The first drain electrode DE1 may be connected to the drain region of the first active pattern ACT1 through a contact hole penetrating the first and second insulating layers IL1 and IL2. The second drain electrode DE2 may be connected to the drain region of the second active pattern ACT2 through a contact hole penetrating the first and second insulating layers IL1 and IL2. The third drain electrode DE3 may be connected to the drain region of the third active pattern ACT3 through a contact hole penetrating the first and second insulating layers IL1 and IL2.

For example, each of the first, second, and third source electrodes SE1, SE2, and SE3 may include metal, alloy, metal nitride, conductive metal oxide, transparent conductive material, and the like. These can be used alone or in combination with each other. The first, second, and third drain electrodes DE1, DE2, and DE3 may be formed through the same process as the first, second, and third source electrodes SE1, SE2, and SE3, and may include the same material as the first, second, and third source electrodes SE1, SE2, and SE3.

The third insulating layer IL3 may be located on the second insulating layer IL2. The third insulating layer IL3 may sufficiently cover the first, second, and third source electrodes SE1, SE2, and SE3 and the first, second, and third drain electrodes DE1, DE2, and DE3. That is, the third insulating layer IL3 may be a planarization layer. The third insulating layer IL3 may include an organic material. For example, the third insulating layer IL3 may include phenolic resin, polyacrylates resin, polyimides rein, polyamides resin, siloxane resin, epoxy resin, and the like. These can be used alone or in combination with each other.

The first-first, first-second, and first-third electrodes E11, E12, and E13 may be located on the third insulating layer IL3. The first-first electrode E11 may overlap the first light emitting area EA1, the first-second electrode E12 may overlap the second light emitting area EA2, and the first-third electrode E13 may overlap the third light emitting area EA3. The first-first electrode E11 may be connected to the first drain electrode DE1 (or the first source electrode SE1) through a contact hole penetrating the third insulating layer IL3, and the first-second electrode E12 may be connected to the second drain electrode DE2 (or the second source electrode SE2) through a contact hole penetrating the third insulating layer IL3. In addition, the first-third electrode E13 may be connected to the third drain electrode DE3 (or the third source electrode SE3) through a contact hole penetrating the third insulating layer IL3.

Each of the first-first, first-second, and first-third electrodes E11, E12, and E13 may be a transmissive electrode, a semi-transmissive electrode, or a reflective electrode. For example, each of the first-first, first-second, and first-third electrodes E11, E12, and E13 may include metal, alloy, metal nitride, conductive metal oxide, transparent conductive material, and the like. These can be used alone or in combination with each other.

The first-first, first-second, and first-third electrodes E11, E12, and E13 may be formed through the same process and may include the same material.

According to some embodiments, each of the first-first, first-second, and first-third electrodes E11, E12, and E13 may be an anode electrode. According to some embodiments, each of the first-first, first-second, and first-third electrodes E11, E12, and E13 may be a cathode electrode.

For example, as shown in FIG. 3, the first-first, first-second, and first-third electrodes E11, E12, and E13 may be patterned to correspond to the first, second, and third light emitting areas EA1, EA2, and EA3, respectively. Alternatively, the first-first, first-second, and first-third electrodes E11, E12, and E13 may be formed integrally and provided as one common layer.

The pixel defining layer PDL may be located on the third insulating layer IL3. The pixel defining layer PDL may overlap the non-light emitting area NEA. A pixel opening exposing at least a portion of an upper surface of each of the first-first, first-second, and first-third electrodes E11, E12, and E13 may be defined in the pixel defining layer PDL. The pixel defining layer PDL may include an inorganic material and/or an organic material. For example, the pixel defining layer PDL may include an organic material such as epoxy resin, siloxane resin, and the like. These can be used alone or in combination with each other. Alternatively, the pixel defining layer PDL may include an inorganic material and/or an organic material containing a light blocking material such as black pigment, black dye, and the like.

According to some embodiments, an upper surface US of the pixel defining layer PDL may have liquid repellent. In this case, a side surface SS of the pixel defining layer PDL may not have liquid repellent. Because the upper surface US of the pixel defining layer PDL has liquid repellent, during an inkjet process to form an intermediate layer (e.g., a layer located between the anode electrode and the cathode electrode), application of an ink composition to the non-light emitting area NEA may be prevented, reduced, or minimized. According to some embodiments, both the upper surface US and the side surface SS of the pixel defining layer PDL may have liquid repellent.

According to some embodiments, the upper surface US of the pixel defining layer PDL may be fluorinated by fluorine-based gas plasma to have liquid-repellent properties (or hydrogen properties). In this case, the upper surface US of the pixel defining layer PDL may include a fluorine group.

According to some embodiments, the hydrogen injection layer HL may surround the side surface SS of the pixel defining layer PDL. For example, the hydrogen injection layer HL may directly contact the side surface SS of the pixel defining layer PDL. As the hydrogen injection layer HL protects the pixel defining layer PDL, the yield of the first, second, and third light emitting elements LED1, LED2, and LED3 may be relatively improved.

According to some embodiments, the hydrogen injection layer HL may expose at least a portion of the upper surface US of the pixel defining layer PDL. That is, the hydrogen injection layer HL may not cover the upper surface US of the pixel defining layer PDL.

As shown in FIG. 4, hydrogen contained in the hydrogen injection layer HL may flow into the first, second, and third light emitting elements LED1, LED2, and LED3. FIG. 4 shows only the hydrogen contained in the hydrogen injection layer HL flowing into the first light emitting element LED1, but the hydrogen contained in the hydrogen injection layer HL may flow into the second and third light emitting elements LED2 and LED3. For example, hydrogen contained in the hydrogen injection layer HL may flow into the electron transport layer of each of the first, second, and third light emitting elements LED1, LED2, and LED3. For example, when the electron transport layer includes zinc oxide, the surface of the electron transport layer may be stabilized due to hydrogen influx. Accordingly, the luminous efficiency of the first, second, and third light emitting elements LED1, LED2, and LED3 may be relatively improved.

For example, the hydrogen injection layer HL may include a silicon compound such as silicon oxide, silicon nitride, silicon oxynitride, and the like. According to some embodiments, the hydrogen injection layer HL may include silicon nitride.

According to some embodiments, a thickness TH of the hydrogen injection layer HL may be in a range from 5 nanometers (nm) or more to 30 nm or less (or about 5 nm or more to about 30 nm or less). If the thickness TH of the hydrogen injection layer HL is less than 5 nm, process distribution defects may occur. When the thickness TH of the hydrogen injection layer HL is greater than 30 nm, the area of the first, second, and third light emitting areas EA1, EA2, and EA3 may be relatively reduced, thereby relatively reducing light emitting quality.

According to some embodiments, when the hydrogen injection layer HL includes silicon nitride, the hydrogen concentration contained in the hydrogen injection layer HL may be in a range from 1.0×10²² atoms/cm³ or more to 1.0×10²³ atoms/cm³ or less (or about 1.0×10²² atoms/cm³ or more to about 1.0×10²³ atoms/cm³ or less).

The first-first functional layer FL11 may be located on the first-first electrode E11, the first-second functional layer FL12 may be located on the first-second electrode E12, and the first-third functional layer FL13 may be located on the first-third the electrode E13. The first-first functional layer FL11 may overlap the first light emitting area EA1, the first-second functional layer FL12 may overlap the second light emitting area EA2, and the first-third functional layer FL13 may overlap the third light emitting area EA3. For example, each of the first-first, first-second, and first-third functional layers FL11, FL12, and FL13 may be located in the pixel opening of the pixel defining layer PDL.

As an example, the first-first, first-second, and first-third electrodes E11, E12, and E13 are anode electrodes and the second electrode E2 is a cathode electrode, components of each of the first-first, first-second, and first-third functional layers FL11, FL12, and FL13 will be described.

Each of the first-first, first-second, and first-third functional layers FL11, FL12, and FL13 may include a hole transport layer. The hole transport layer may serve to facilitate injection of holes from a first electrode (e.g., the first-first electrode E11, the first-second E12, or the first-third E13) to a light emitting layer (e.g., the first light emitting layer EML1, the second light emitting layer EML2, or the third light emitting layer EML3).

For example, the hole transport layer may include carbazole-based derivatives such as N-phenylcarbazole and polyvinylcarbazole, fluorene-based derivatives, TPD(N,N′-bis(3-methylphenyl)-N,N′-diphenyl-[1,1-biphenyl]-4,4′-diamine), triphenylamine derivatives such as TCTA (4,4′,4″-tris(N-carbazolyl)triphenylamine), NPD(N,N′-di(naphthalene-I-yl)-N,N′-diphenyl-benzidine), TAPC(4,4′-Cyclohexylidenebis[N,Nbis(4-methylphenyl)benzenamine]), HMTPD(4,4′-Bis[N,N′-(3-tolyl)amino]-3,3′-dimethylbiphenyl), mCP(1,3-Bis(N-carbazolyl)benzene), and the like. These can be used alone or in combination with each other. However, embodiments according to the present disclosure are not necessarily limited thereto.

Each of the first-first, first-second, and first-third functional layers FL11, FL12, and FL13 may further include a hole injection layer in addition to the hole transport layer. In this case, the hole injection layer may be located between each of the first-first, first-second, and first-third electrodes E11, E12, and E13 and the hole transport layer. The hole injection layer may relatively improve hole injection characteristics into the hole transport layer without increasing the driving voltage. For example, the hole injection layer may include common materials known in the art.

For example, as shown in FIG. 3, the first-first, first-second, and first-third functional layers FL11, FL12, and FL13 may be arranged to be spaced apart from each other. Alternatively, the first-first, first-second, and first-third functional layers FL11, FL12, and FL13 may be formed integrally and provided as one common layer.

The first light emitting layer EML1 may be located on the first-first electrode E11, the second light emitting layer EML2 may be located on the first-second electrode E12, and the third light emitting layer EML3 may be located on the first-third electrode E13. The first light emitting layer EML1 may overlap the first light emitting area EA1, the second light emitting layer EML2 may overlap the second light emitting area EA2, and the third light emitting layer EML3 may overlap the third light emitting area EA3. For example, the first, second, and third light emitting layers EML1, EML2, and EML3 may be located in the pixel opening of the pixel defining layer PDL.

According to some embodiments, the first light emitting layer EML1 may include first quantum dots QD1, the second light emitting layer EML2 may include second quantum dots QD2, and the third light emitting layer EML3 may include third quantum dots QD3. For example, the first quantum dots QD1 may emit light of a first color, the second quantum dots QD2 may emit light of a second color, and the third quantum dots QD3 may emit light of a third color.

For example, the first color light may be red light, the second color light may be green light, and the third color light may be blue light.

For example, the first, second, and third quantum dots QD1, QD2, and QD3 may include a group II-VI compound, a group III-V compound, a group IV-VI compound, a group IV element, a group IV compound, and the like. These can be used alone or in combination with each other.

For example, each of the first, second, and third quantum dots QD1, QD2, and QD3 may have a core-shell structure including a core and a shell surrounding the core. The shell may serve as a protective layer to maintain semiconductor properties by preventing or reducing chemical denaturation of the core, and serve as a charging layer to provide electrophoretic properties to the first, second, and third quantum dots QD1, QD2, and QD3.

The second-first functional layer FL21 may be located on the first light emitting layer EML1, the second-second functional layer FL22 may be located on the second light emitting layer EML2, and the second-third functional layer FL23 may be located on the third light emitting layer EML3.

The second-first functional layer FL21 may overlap the first light emitting area EA1, the second-second functional layer FL22 may overlap the second light emitting area EA2, and the second-third functional layer FL23 may overlap the third light emitting area EA3. For example, the second-first, second-second, and second-third functional layers FL21, FL22, and FL23 may be located in the pixel opening of the pixel defining layer PDL.

As an example, the first-first, first-second, and first-third electrodes E11, E12, and E13 are anode electrodes and the second electrode E2 is a cathode electrode, and components of each of the second-first, second-second, and second-third functional layers FL21, FL22, and FL23 will be described.

Each of the second-first, second-second, and second-third functional layers FL21, FL22, and FL23 may include an electron transport layer. The electron transport layer may transfer electrons from the second electrode E2 to the light emitting layer.

For example, the electron transport layer may include inorganic particles, peroxides, hydrocarbon compounds, and solvents. The inorganic particles may serve to transport electrons injected from the second electrode E2. The inorganic particles may include metal oxide. For example, the metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂, Y₂O₃, and the like, or a ternary compound such as ZnMgO, MgAl₂O₄, CoFe₂O₄, NiFe₂O₄, CoMn₂O₄, BaTiO₃, BaZrO₃, ZrSiO₄, and the like. These can be used alone or in combination with each other. However, embodiments according to the present disclosure are not necessarily limited thereto.

Each of the second-first, second-second, and second-third functional layers FL21, FL22, and FL23 may further include an electron injection layer in addition to the electron transport layer. In this case, the electron injection layer may be located between the second electrode E2 and the electron transport layer. The electron injection layer may relatively improve electron injection characteristics into the electron transport layer without increasing the driving voltage.

For example, as shown in FIG. 3, the second-first, second-second, and second-third functional layers FL21, FL22, and FL23 may be arranged to be spaced apart from each other. Alternatively, the second-first, second-second, and second-third functional layers FL21, FL22, and FL23 may be formed integrally and provided as one common layer.

The second electrode E2 may be located on the second-first, second-second, and second-third functional layers FL21, FL22, and FL23. The second electrode E2 may be a transmissive electrode, a semi-transmissive electrode, or a reflective electrode. For example, the second electrode E2 may include metal, alloy, metal nitride, conductive metal oxide, transparent conductive material, and the like. These can be used alone or in combination with each other.

According to some embodiments, the second electrode E2 may be a cathode electrode. According to some embodiments, the second electrode E2 may be an anode electrode.

According to some embodiments, the second electrode E2 may be formed integrally and provided as one common layer.

The encapsulation layer TFE may be located on the second electrode E2. The encapsulation layer TFE may cover the first, second, and third light emitting elements LED1, LED2, and LED3. The encapsulation layer TFE may include at least one inorganic layer and at least one organic layer. For example, the encapsulation layer TFE may include a first inorganic layer, an organic layer, and a second inorganic layer sequentially stacked. The inorganic layer of the encapsulation layer TFE may protect the first, second, and third light emitting elements LED1, LED2, and LED3 from external moisture, and the organic layer of the encapsulation layer TFE may protect defects in the first, second, and third light emitting elements LED1, LED2, and LED3 caused by foreign substances introduced during the manufacturing process.

The optical member PP may be located on the encapsulation layer TFE. The optical member PP may block external light provided to the display panel DP from outside the display panel DP. That is, the optical member PP may perform an anti-reflection function that minimizes reflection by external light. Hereinafter, the configurations of the optical member PP will be described.

The second substrate SUB2 may include a glass substrate, a metal substrate, or a plastic substrate. However, embodiments according to the present invention are not necessarily limited thereto. For example, the second substrate SUB2 may include an inorganic layer, an organic layer, or a composite material layer.

The first, second, and third color filters CF1, CF2, and CF3 may be located under the second substrate SUB2. The first, second, and third color filters CF1, CF2, and CF3 may selectively transmit light of a specific wavelength.

The first color filter CF1 may transmit light of the first color (e.g., red light). For example, the first color filter CF1 may include red pigment or dye. The second color filter CF2 may transmit the second color light (e.g., green light). For example, the second color filter CF2 may include green pigment or dye. The third color filter CF3 may transmit the third color light (e.g., blue light). For example, the third color filter CF3 may include blue pigment or dye. However, embodiments according to the present disclosure are not limited thereto.

For example, the third color filter CF3 may partially overlap the first color filter CF1 and the second color filter CF2 in a plan view, respectively. However, embodiments according to the present disclosure are not necessarily limited to this, and the first, second, and third color filters CF1, CF2, and CF3 do not overlap each other in the plan view, and the first, second, and third color filters CF1, CF2, and CF3 may be arranged to overlap the first, second, and third light emitting areas EA1, EA2, and EA3, respectively. Alternatively, the first, second, and third color filters CF1, CF2, and CF3 may be omitted.

The light blocking layer BM may be located under the first, second, and third color filters CF1, CF2, and CF3. The light blocking layer BM may overlap the non-light emitting area NEA. The light blocking layer BM may be a black matrix. For example, the light blocking layer BM may include an organic light blocking material or an inorganic light blocking material containing black pigment or black dye. The light blocking layer BM may prevent or reduce light leakage and distinguish boundaries between adjacent first, second, and third color filters CF1, CF2, and CF3.

The protective layer BFL may be located under the light blocking layer BM and the first, second, and third color filters CF1, CF2, and CF3. The protective layer BFL may cover the light blocking layer BM and the first, second, and third color filters CF1, CF2, and CF3. The protective layer BFL may protect the first, second, and third color filters CF1, CF2, and CF3. For example, the protective layer BFL may include a silicon compound such as silicon oxide, silicon nitride, silicon oxynitride, and the like. These can be used alone or in combination with each other.

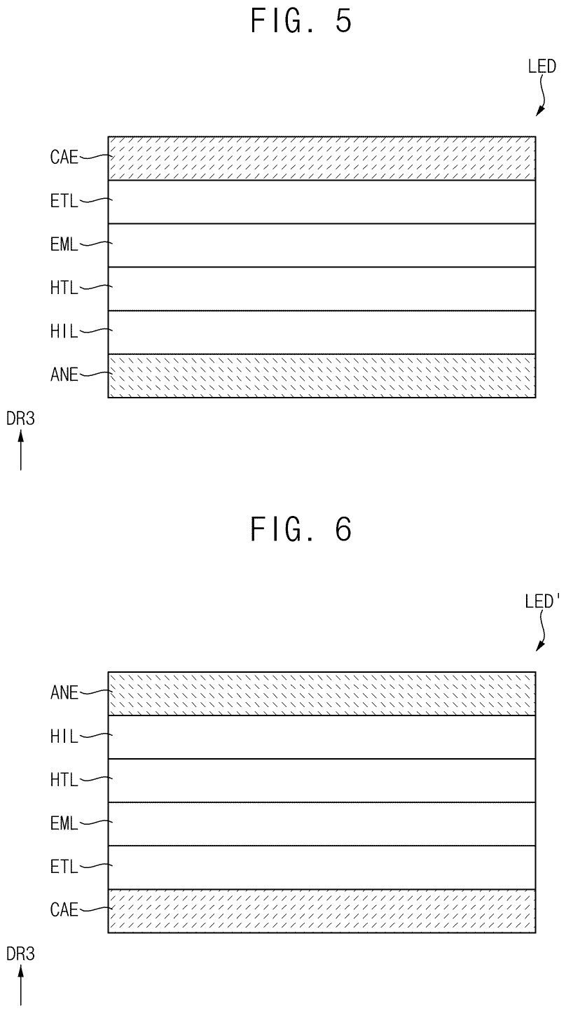

FIG. 5 is a cross-sectional view showing an example of a light-emitting element.

Referring to FIG. 5, the light emitting element LED may include an anode electrode ANE, a hole injection layer HIL, a hole transport layer HTL, a light emitting layer EML, and an electron transport layer ETL, and cathode electrode CAE sequentially stacked along the third direction DR3. At this time, the light emitting layer EML may include quantum dots and may emit light along the third direction DR3.

According to some embodiments, each of the first, second, and light emitting elements LED1, LED2, and LED3 of FIG. 3 may have the same structure as the light emitting element LED of FIG. 5. In this case, each of the first-first, first-second, and first-third electrodes E11, E12, and E13 of FIG. 3 may correspond to the anode electrode ANE, each of the first-first, first-second, and first-third functional layers FL11, FL12, and FL13 of FIG. 3 may correspond to the hole injection layer HIL and the hole transport layer HTL, and each of the second-first, second-second, and second-third functional layers FL21, FL22, and FL23 of FIG. 3 may correspond to the electron transport layer ETL, and the second electrode E2 of FIG. 3 may correspond to the cathode electrode CAE.

FIG. 6 is a cross-sectional view showing another example of a light-emitting element.

Referring to FIG. 6, a light emitting element LED′ may include a cathode electrode CAE, an electron transport layer ETL, a light emitting layer EML, a hole transport layer HTL, a hole injection layer HIL, and an anode electrode ANE sequentially stacked along the third direction DR3. At this time, the light emitting layer EML may include quantum dots and may emit light along the third direction DR3.

According to some embodiments, each of the first, second, and third light emitting elements LED1, LED2, and LED3 of FIG. 3 may have the same structure as the light emitting element LED′ of FIG. 6. In this case, each of the first-first, first-second, and first-third electrodes E11, E12, and E13 of FIG. 3 may correspond to the cathode electrode CAE, each of the first-first, first-second, and first-third functional layers FL11, FL12, and FL13 of FIG. 3 may correspond to the electron transport layer ETL, each of the second-first, second-second, and second-third functional layers FL21, FL22, and FL23 of FIG. 3 may correspond to the hole transport layer HTL and the hole injection layer HIL, and the second electrode E2 of FIG. 3 may correspond to the anode electrode ANE.

Referring again to FIGS. 1, 2, 3, 4, 5, and 6, the display device DD according to some embodiments of the present disclosure may include a light emitting element (e.g., the first light emitting element LED1, the second light emitting element LED2, or the third light emitting element LED3) including a first electrode (e.g., the first electrode E1, the second electrode E2, or the third electrode E3), a light-emitting layer (e.g., the first light emitting layer EML1, the second light emitting layer EML2, or the third light emitting layer EML3) including quantum dots, and the second electrode E2 sequentially arranged, the pixel defining layer PDL defining the pixel opening exposing at least a portion of the upper surface of the first electrode and where the light emitting layer is located, and the hydrogen injection layer HL surrounding the side surface SS of the pixel defining layer PDL and including silicone compound.

At this time, hydrogen contained in the hydrogen injection layer HL may flow into the light emitting element (for example, an electron transport layer). Accordingly, the luminous efficiency and luminance of the light emitting element may be relatively improved. In addition, by protecting the side surface SS of the pixel defining layer PDL with the hydrogen injection layer HL, the yield of the light emitting element may be relatively improved.

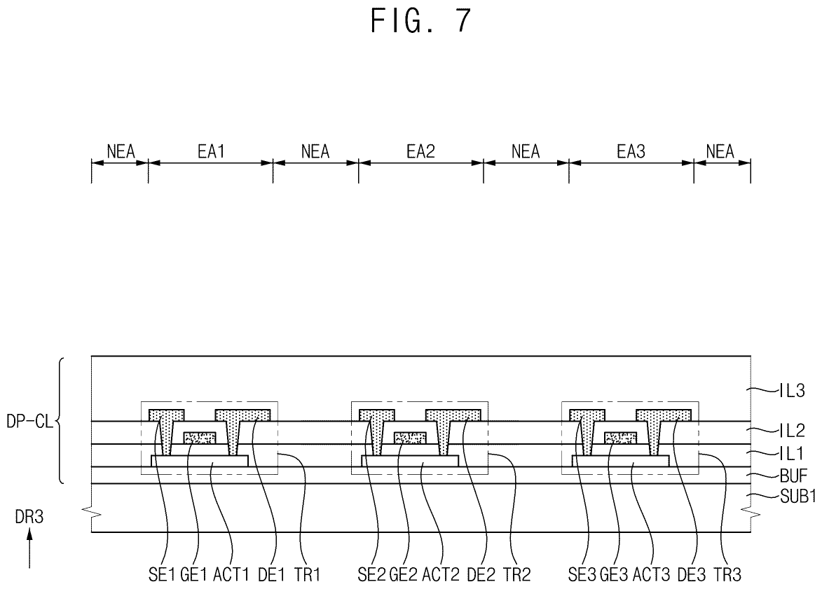

FIGS. 7, 8, 9, 10, 11, 12, and 13 are cross-sectional views for explaining a method for manufacturing the display device of FIG. 3. Hereinafter, overlapping descriptions of the display device DD described with reference to FIGS. 3, 4, 5, and 6 will be omitted or simplified.

Referring to FIG. 7, the buffer layer BUF, the first, second, and third active patterns ACT1, ACT2, and ACT3, the first insulating layer IL1, the first, second, and third gate electrodes GE1, GE2, and GE3, the second insulating layer IL2, the first, second, and third source electrodes SE1, SE2, and SE3, the first, second, and third drain electrodes DE1, DE2, and DE3, and the third insulating layers IL3 may be formed sequentially on the first substrate SUB1.

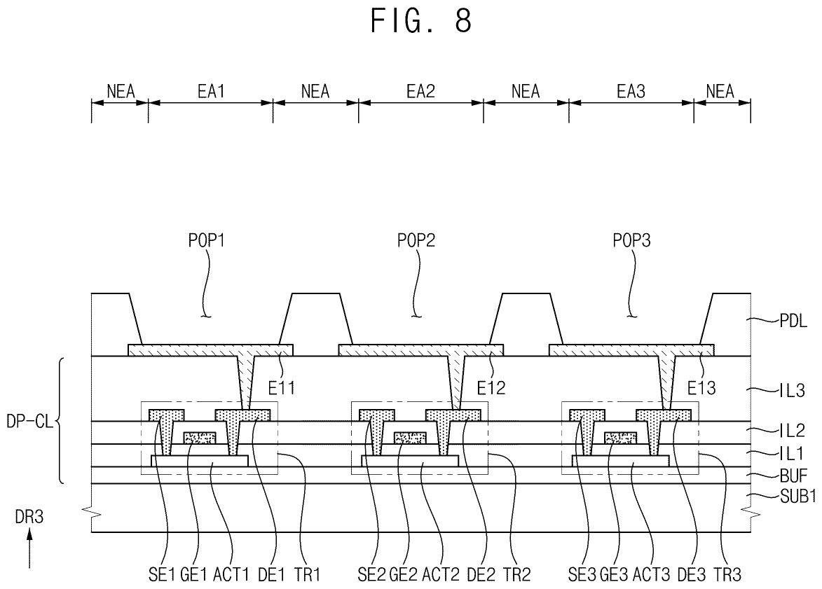

Referring to FIG. 8, the first-first, first-second, and first-third electrodes E11, E12, and E13 may be formed on the third insulating layer IL3. The first-first electrode E11 may be formed in the first light emitting area EA1, the first-second electrode E12 may be formed in the second light emitting area EA2, and the first-third electrode E13 may be formed in the third light emitting area EA3. For example, the first-first, first-second, and first-third electrodes E11, E12, and E13 may be formed simultaneously through the same etching process.

The pixel defining layer PDL may be formed on the third insulating layer IL3. The pixel defining layer PDL may be formed in the non-light emitting area NEA. A first pixel opening POP1 exposing at least a portion of an upper surface of the first-first electrode E11, a second pixel opening POP2 exposing at least a portion of an upper surface of the first-second electrode E12, and a third pixel opening POP3 exposing at least a portion of an upper surface of the first-third electrode E13 may be defined (or formed) in the pixel defining layer PDL.

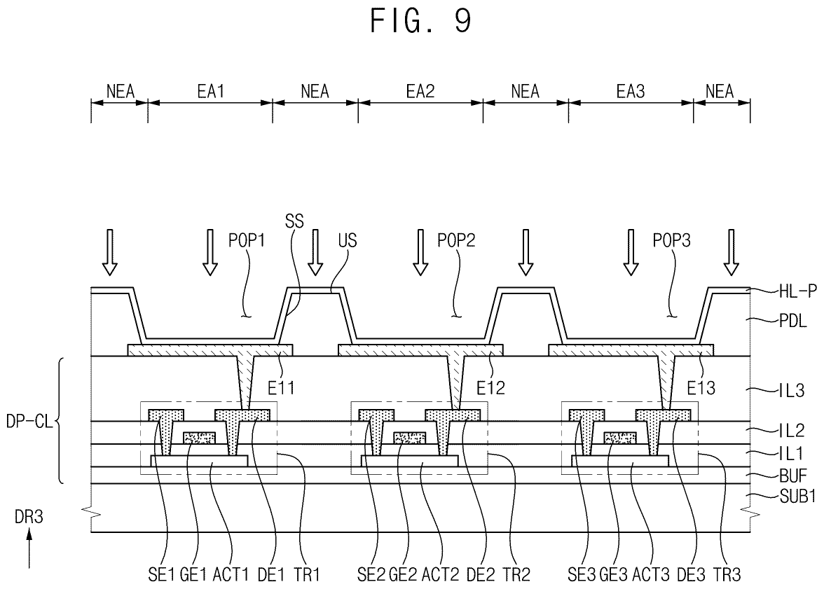

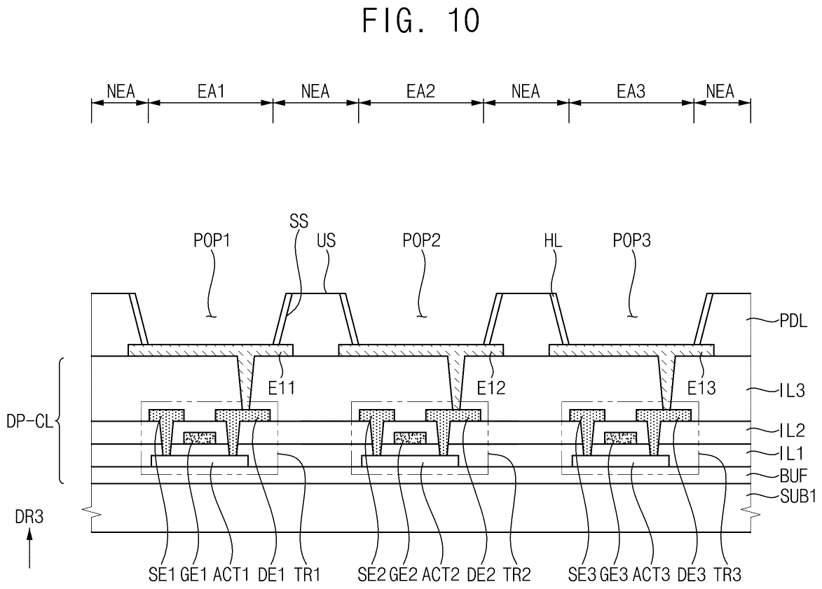

Referring to FIGS. 9 and 10, a preliminary hydrogen injection layer HL-P may be formed on the first-first, first-second, and first-third electrodes E11, E12, and E13 and the pixel defining layer PDL. The preliminary hydrogen injection layer HL-P may be formed entirely in the first, second, and third light emitting areas EA1, EA2, and EA3 and the non-light emitting area NEA.

According to some embodiments, the preliminary hydrogen injection layer HL-P may be formed using silicon nitride. For example, in this case, the preliminary hydrogen injection layer HL-P may be formed through supply and combination of ammonium (NH₃) and silane (SiH₄).

According to some embodiments, the hydrogen concentration contained in the preliminary hydrogen injection layer HL-P may be in a range from 1.0×10²² atoms/cm³ or more to 1.0×10²³ atoms/cm³ or less (or about 1.0×10²² atoms/cm³ or more to about 1.0×10²³ atoms/cm³ or less).

For example, the preliminary hydrogen injection layer HL-P may be formed by chemical vapor deposition (CVD). According to some embodiments, the deposition temperature for forming the preliminary hydrogen injection layer HL-P may be in a range from 25° C. or more to 100° C. or less (or about 25° C. or more to about 100° C. or less). If the deposition temperature is less than 25° C., the plasma reaction may not occur and the preliminary hydrogen injection layer HL-P may not be deposited. If the deposition temperature is higher than 100° C., film bursting defects may occur in the organic film (e.g., the pixel defining film PDL) formed around the preliminary hydrogen injection layer HL-P.

A portion of the preliminary hydrogen injection layer HL-P may be removed through an etching process. For example, the etching process may be a dry etching process. According to some embodiments, the dry etching process may use a fluorine-based etching gas. For example, the fluorine-based etching gas may include carbon tetrafluoride (CF₄), nitrogen trifluoride (NF₃), sulfur hexafluoride (SF₆), and the like. These can be used alone or in combination with each other.

A portion of the preliminary hydrogen injection layer HL-P may be removed through the etching process, thereby forming the hydrogen injection layer HL surrounding the side surface SS of the pixel defining layer PDL. When the etching process uses a fluorine-based etching gas, fluorine groups may flow into the upper surface of the pixel defining layer PDL. Accordingly, the upper surface US of the pixel defining layer PDL is treated to be liquid repellent, so that the upper surface US of the pixel defining layer PDL may have liquid repellent.

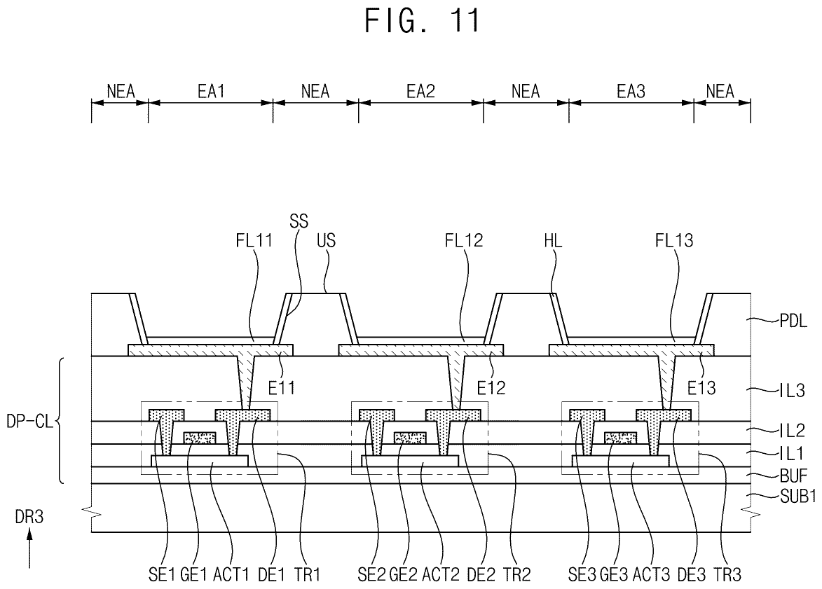

Referring to FIG. 11, the first-first functional layer FL11 may be formed in the first light emitting area EA1 on the first-first electrode E11, the first-second functional layer FL12 may be formed on in the second light emitting area EA2 on the first-second electrode E12, and the first-third functional layer FL13 may be formed on in the third light emitting area EA3 on the first-third electrode E13. For example, the first-first functional layer FL11 may be formed inside the first pixel opening POP1, the first-second functional layer FL12 may be formed inside the second pixel opening POP2, and the first-third functional layer FL13 may be formed inside the third pixel opening POP3.

For example, each of the first-first, first-second, and first-third functional layers FL11, FL12, and FL13 may be formed by an inkjet printing method. Alternatively, each of the first-first, first-second, and first-third functional layers FL11, FL12, and FL13 may be formed using various methods such as vacuum deposition method, spin coating method, Langmuir-Blodegtt (LB) method, laser printing method, laser induced thermal imaging (LITI), or the like. However, embodiments according to the present disclosure are not necessarily limited thereto.

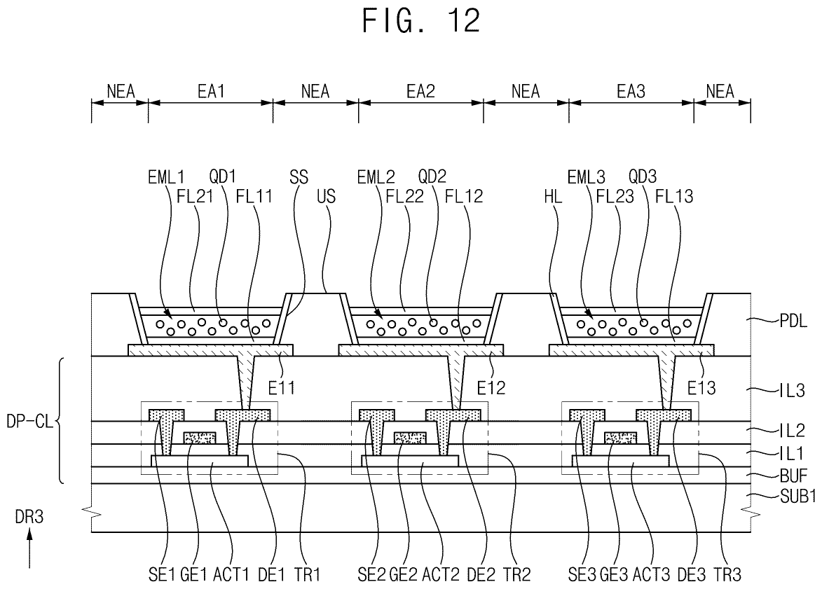

Referring to FIG. 12, the first light emitting layer EML1 may be formed in the first light emitting area EA1 on the first-first functional layer FL11, the second light emitting layer EML2 may be formed in the second light emitting area EA2 on the first-second functional layer FL12, and the third light emitting layer EML3 may be formed in the third light emitting area EA3 on the first-third functional layer FL13. For example, the first light emitting layer EML1 may be formed inside the first pixel opening POP1, the second light emitting layer EML2 may be formed inside the second pixel opening POP2, and the third light emitting layer EML3 may be formed inside the third pixel opening POP3.

The first, second, and third light emitting layers EML1, EML2, and EML3 may be formed by applying a solution in which the first, second, and third quantum dots QD1, QD2, and QD3 are dispersed, respectively, through a solution process. For example, the solution process may be an inkjet printing method. Alternatively, the solution process may be any one of spin coating method, casting, and spraying method. However, embodiments according to the present disclosure are not necessarily limited thereto.

The second-first functional layer FL21 may be formed in the first light emitting area EA1 on the first light emitting layer EML1, the second-second functional layer FL22 may be formed in the second light emitting area EA2 on the second light emitting layer EML2, and the second-third functional layer FL23 may be formed in the third light emitting area EA3 on the second light emitting layer EML3. For example, the second-first functional layer FL21 may be formed inside the first pixel opening POP1, the second-second functional layer FL22 may be formed inside the second pixel opening POP2, and the second-third functional layer FL23 may be formed inside the third pixel opening POP3.

For example, each of the second-first, second-second, and second-third functional layers FL21, FL22, and FL23 may be formed by an inkjet printing method. Alternatively, each of the second-first, second-second, and second-third functional layers FL21, FL22, and FL23 may be formed using various methods such as vacuum deposition method, spin coating method, LB method, laser printing method, laser induced thermal imaging metho, or the like. However, embodiments according to the present disclosure are not necessarily limited thereto.

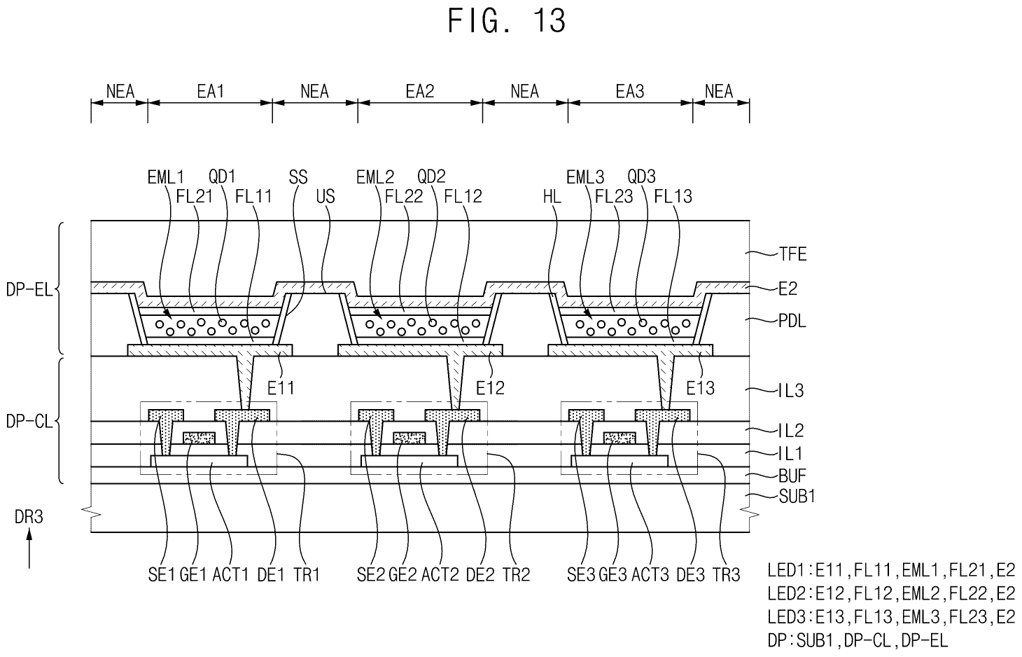

Referring to FIG. 13, the second electrode E2 may be formed on the pixel defining layer PDL and the second-first, second-second, and second-third functional layers FL21, FL22, and FL23. The second electrode E2 may be formed entirely in the first, second, and third light emitting areas EA1, EA2, and EA3 and the non-light emitting area NEA.

Referring again to FIG. 3, the optical member PP including the second substrate SUB2, the first, second, and third color filters CF1, CF2, and CF3 formed under the second substrate SUB2, the light blocking layer BM formed under the first, second, and third color filters CF1, CF2, and CF3, and the protective layer BFL formed under the light blocking layer BM may be manufactured.

The optical member PP may be attached to the light emitting element layer DP-EL. Accordingly, the display device DD shown in FIG. 3 may be manufactured.

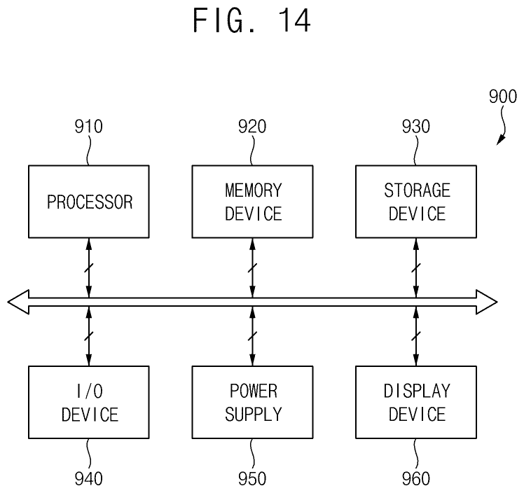

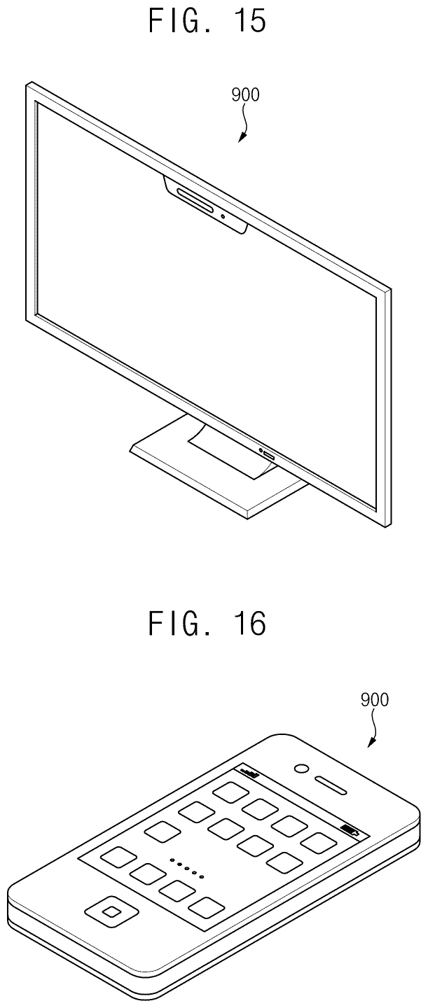

FIG. 14 is a block diagram showing an electronic device including the display device of FIG. 1. FIG. 15 is a view illustrating an example in which the electronic device of FIG. 9 is implemented as a television. FIG. 16 is a view illustrating an example in which the electronic device of FIG. 9 is implemented as a smartphone.

Referring to FIGS. 14, 15, and 16, according to some embodiments, an electronic device 900 may include a processor 910, a memory device 920, a storage device 930, an input/output device 940, a power supply 950, and a display device 960. In this case, the display device 960 may correspond to the display device DD described with reference to FIGS. 1, 2, and 3. The electronic device 900 may further include several ports capable of communicating with a video card, a sound card, a memory card, a USB device, and the like.

According to some embodiments, as shown in FIG. 15, the electronic device 900 may be implemented as a television. According to some embodiments, as shown in FIG. 16, the electronic device 900 may be implemented as a smartphone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. According to some embodiments, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. According to some embodiments, the display device 960 may be included in the input/output device 940.

Embodiments according to the present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of aspects of some embodiments and is not to be construed as limiting thereof. Although a few embodiments have been described, those skilled in the art will readily appreciate that many modifications are possible in the embodiments without materially departing from the novel teachings and characteristics of embodiments according to the present disclosure. Accordingly, all such modifications are intended to be included within the scope of embodiments according to the present disclosure as defined in the appended claims, and their equivalents. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a substrate including a light emitting area and a non-light emitting area adjacent to the light emitting area;
a circuit layer on the substrate;
a light emitting element in the light emitting area on the circuit layer and including a first electrode, a light emitting layer including quantum dots and on the first electrode, and a second electrode on the light emitting layer;
a pixel defining layer in the non-light emitting area on the circuit layer, and defining a pixel opening exposing at least a portion of an upper surface of the first electrode and where the light emitting layer is located; and
a hydrogen injection layer surrounding a side surface of the pixel defining layer and including silicone compound.

2. The display device of claim 1, wherein the hydrogen injection layer includes silicon nitride (SiNₓ).

3. The display device of claim 1, wherein the hydrogen injection layer exposes an upper surface of the pixel defining layer.

4. The display device of claim 1, wherein an upper surface of the hydrogen injection layer has a liquid repellent.

5. The display device of claim 1, wherein an upper surface of the hydrogen injection layer includes a fluorine group.

6. The display device of claim 1 wherein a thickness of the hydrogen injection layer is in a range from 5 nanometers (nm) to 30 nm.

7. The display device of claim 1, wherein a hydrogen concentration contained in the hydrogen injection layer is in a range of 1.0×10²² atoms/cm³ to 1.0×10²³ atoms/cm³.

8. The display device of claim 1, wherein the hydrogen injection layer exposes at least portion of the upper surface of the first electrode in the pixel opening.

9. The display device of claim 1, wherein the circuit layer includes at least one transistor including an oxide semiconductor.

10. The display device of claim 1, wherein the pixel defining layer includes an organic material or an inorganic material.

11. The display device of claim 1, wherein the first electrode is an anode electrode, the second electrode is a cathode electrode, and
the light emitting element further includes:
a hole transport layer between the first electrode and the light emitting layer;
a hole injection layer between the first electrode and the hole transport layer; and
an electron transport layer between the light emitting layer and the second electrode.

12. The display device of claim 1, wherein the first electrode is a cathode electrode, the second electrode is an anode electrode, and
the light emitting element further includes:
an electron transport layer between the first electrode and the light emitting layer;
a hole transport layer between the light emitting layer and the second electrode; and
a hole injection layer between the light emitting layer and the hole transport layer.

13. A method for manufacturing a display device, the method comprising:
forming a circuit layer on a substrate including a light emitting area and a non-light emitting area adjacent to the light emitting area;
forming a first electrode in the light emitting area on the circuit layer;
forming a pixel defining layer in the non-light emitting area on the circuit layer, and defining a pixel opening exposing at least a portion of an upper surface of the first electrode;
forming a hydrogen injection layer surrounding a side surface of the pixel defining layer and including silicone compound;
forming a light emitting layer including quantum dots on the first electrode; and
forming a second electrode on the light emitting layer.

14. The method of claim 13, wherein the forming the hydrogen injection layer includes:
forming a preliminary hydrogen injection layer on the first electrode and on the pixel defining layer; and
forming the hydrogen injection layer by removing a portion of the preliminary hydrogen injection layer through an etching process.

15. The method of claim 14, wherein the etching process uses a fluorine-based etching gas.

16. The method of claim 15, wherein the fluorine-based etching gas includes at least one selected from a group consisting of CF₄, NF₃, and SF₆.

17. The method of claim 14, wherein the preliminary hydrogen injection layer is formed by chemical vapor deposition, and
a deposition temperature for forming preliminary hydrogen injection layer is in a range from 25° C. or more to 100° C. or less.

18. The method of claim 13, wherein the hydrogen injection layer is formed using silicon nitride.

19. The method of claim 13, wherein the hydrogen injection layer exposes an upper surface of the pixel defining layer, and
after forming the hydrogen injection layer, an upper surface of the pixel defining layer has liquid repellent.

20. An electronic device comprising:
a display device; and
a processor configured to control the display device,
wherein the display device includes:
a substrate including a light emitting area and a non-light emitting area adjacent to the light emitting area;
a circuit layer on the substrate;
a light emitting element in the light emitting area on the circuit layer and including a first electrode, a light emitting layer including quantum dots and on the first electrode, and a second electrode on the light emitting layer;
a pixel defining layer in the non-light emitting area on the circuit layer, and defining a pixel opening exposing at least a portion of an upper surface of the first electrode and where the light emitting layer is located; and
a hydrogen injection layer surrounding a side surface of the pixel defining layer and including silicone compound.
